(19) United States
(12) Patent Application Publication
(10) Pub. No.: US 2005/0157480 A1
(43) Pub. Date: Jul. 21, 2005

(54) Waterproof, vibration-proof, and heat dissipative housing of an electronic element

(76) Inventors: Huei-Hsin Sun, Taipei City (TW); Yu-Yu Chuang, Banchiau City (TW)

Correspondence Address: NIKOLAI & MERSEREAU, P.A., 900 SECOND AVENUE SOUTH, SUITE 820, MINNEAPOLIS, MN, 55402, US

(21) Appl. No.: 10/759,706

(22) Filed: Jan. 16, 2004

(51) Int. Cl. H05K 7/14; H05K 7/18

(52) U.S. Cl. 361/797

(57) ABSTRACT

A housing for enclosing an electronic element of an electronic device is formed of plastic material without electromagnetic waves shielding capability and includes a first hole for injecting fluid of nonconductive, non-corrosive, and high heat transfer capability (e.g., silicon oil or hydro oil) or a semisolid substance having similar properties thereinto, a second hole for evacuating air, and two stop members inserted in the holes for sealing after the injection. The electronic element is adapted to be waterproof and vibration-proof, and has a predetermined heat dissipation capability.

### BACKGROUND OF THE INVENTION

1. Field of the Invention

The present invention relates to housings of electronic elements and more particularly to an improved housing injected with fluid (e.g., silicon oil or hydro oil) or a semisolid substance and formed on an electronic element (e.g., CPU) so that the electronic element is waterproof and vibration-proof, and has an acceptable heat dissipation capability.

2. Description of Related Art

Products have waterproof, vibration-proof, and/or heat dissipative capabilities are well known. For example, for being waterproof sealing members or the like are provided in a product. But prior art is unsatisfactory for the purpose for which the invention is concerned. Thus, continuing improvements in the exploitation of waterproof, vibration-proof, and heat dissipative devices are constantly being sought.

### SUMMARY OF THE INVENTION

It is an object of the present invention to provide a housing for enclosing an electronic element of an electronic device, comprising a first hole for injecting fluid of nonconductive, non-corrosive, and high heat transfer capability (e.g., silicon oil or hydro oil) or a semisolid substance having similar properties thereinto, a second hole for evacuating air, and two stop members inserted in the holes for sealing after the injection. By utilizing the present invention, the electronic element is adapted to be waterproof and vibration-proof, and has a predetermined heat dissipation capability.

In one aspect of the present invention the housing is formed of plastic material without electromagnetic waves shielding capability.

The above and other objects, features and advantages of the present invention will become apparent from the following detailed description taken with the accompanying drawings.

### BRIEF DESCRIPTION OF THE DRAWINGS

FIG. 1 is a perspective, phantom view of a preferred embodiment of housing of an electronic element according to the invention.

### DETAILED DESCRIPTION OF THE PREFERRED EMBODIMENTS

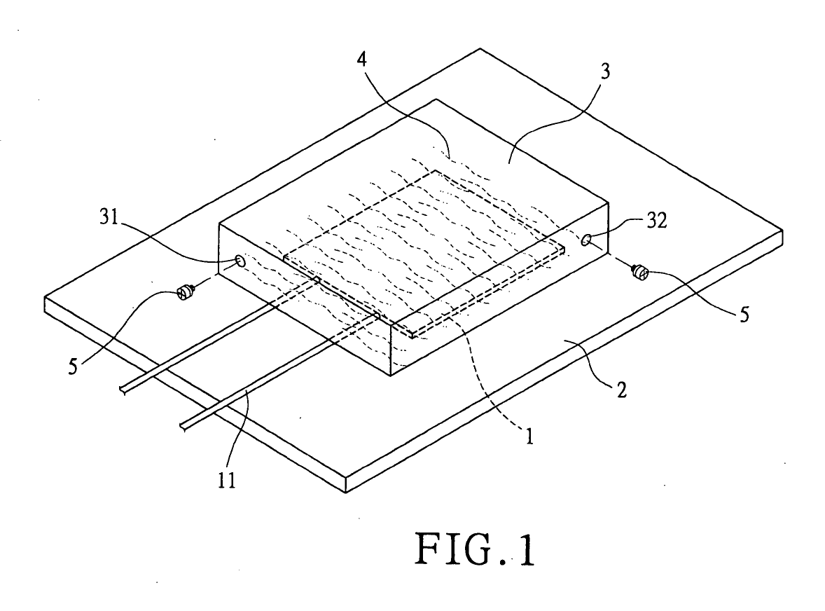

Referring to FIG. 1, there is shown a parallelepiped housing 3 in accordance with the invention. The housing 3 is mounted on a circuit board 2 of an electronic device (e.g., notebook computer, PDA, cellular phone, or the like). A heat source (e.g., CPU or the like) 1 on the circuit board 2 is the component enclosed by the housing 3. Two data lines (or power cords or antennas) 11 are extended from the heat source 1. The housing 3 is formed of plastic material (e.g., rubber) without electromagnetic waves shielding capability. The housing 3 comprises a first hole 31 for permitting fluid 4 of nonconductive, non-corrosive, and high heat transfer capability (e.g., silicon oil or hydro oil) or a semisolid substance having similar properties (in other embodiments) to inject thereinto, and a second hole 32 for permitting air to exit while injecting. Alternatively, evacuate air from the housing 3 to the highest possible degree prior to the injection. Insert stop members 5 in the holes 31 and 32 for sealing after the injection has been finished (i.e., the housing 3 is full of fluid 4). As a result, the electronic element 1 is waterproof and vibration-proof, and has an acceptable heat dissipation capability.

While the invention herein disclosed has been described by means of specific embodiments, numerous modifications and variations could be made thereto by those skilled in the art without departing from the scope and spirit of the invention set forth in the claims.

1. An assembly for enclosing an electronic element of an electronic device, comprising:
a housing enclosing the electronic element;
a first hole in the housing;
a second hole in the housing;
a substance of nonconductive, non-corrosive, and high heat capability and which is injectable into the first hole of the housing while air is evacuated from the second hole of the housing to completely fill the housing with the substance; and
two stop members inserted into the holes for sealing the housing after the substance completely fills the housing so that the electronic element is adapted to be waterproof and vibration-proof, and has a predetermined heat dissipation capability, wherein the housing is formed of plastic material without electromagnetic waves shielding capability.

2. (canceled)

3. The assembly of claim 1, wherein the plastic material is rubber.

4. The assembly of claim 1, wherein the substance is a fluid.

5. The assembly of claim 4, wherein the fluid is silicon oil.

6. The assembly of claim 4, wherein the fluid is hydro oil.

7. The assembly of claim 1, wherein the substance is semisolid.
